(19) United States
(12) Patent Application Publication
(10) Pub. No.: US 2008/0121516 A1
(43) Pub. Date: May 29, 2008

(54) Method and apparatus for treating sputtering target to reduce burn-in time and sputtering targets made thereby

(76) Inventors: Jaydeep Sarkar, Thiells, NY (US); Peter McDonald, Pearl River, NY (US); Paul S. Gilman, Suffern, NY (US)

Correspondence Address: PRAXAIR, INC.;LAW DEPARTMENT - M1 557, 39 OLD RIDGEBURY ROAD, DANBURY, CT, 06810-5113, US

(21) Appl. No.: 11/605,406

(22) Filed: Nov. 29, 2006

(51) Int. Cl. C23C 14/02

(52) U.S. Cl. 204/192.12

(57) ABSTRACT

A method for dry treating a sputter target using a plasma to significantly reduce burn-in time of the target by removing surface contaminants and also a minimal thickness of the deformed layer characteristics of a machined surface, the target so produced, and apparatus used for the target treatment.

### FIELD OF THE INVENTION

The present invention relates to a method of reducing sputtering target conditioning time, also known as burn-in time. More particularly, the present invention relates to methods of surface preparation of a sputtering target to achieve suitable surface properties that advantageously reduce burn-in time of the target, and apparatuses for the treating thereof.

### BACKGROUND OF THE INVENTION

In the manufacture of sputtering targets used for many applications, such as those often found in the semi-conductor industry, it is desirable to produce a sputter target with a sputter surface that will provide desirable film properties such as low enough Rs uniformity, reduced particle counts, etc. The typical manufacturing processes for sputter targets result in targets with residual surface contaminations and deformed layers. Contaminations are often chemical in nature whereas deformed layers are of metallurgical nature. The materials comprising the sputter targets, such as titanium, aluminum, nickel, chromium, cobalt, copper and alloys thereof, have inherent problems in providing low enough Rs uniformity, and reduced particle content before a complete burn-in of target for several hours. Deformed layers and contaminations are results of the processing steps such as final polishing, cleaning and packaging. Residual contaminants and the presence of deformed layers at the surface generally have adverse effects on the sputter performance and, consequently, on the finial film properties.

Targets used in the present day sputtering systems are generally conditioned or burned-in for a substantial length of time (at least 1 to 6 hours) before they can be used for film deposition on the production wafers in the manufacturing environment. The purpose of the burn-in process is to remove any residual contaminants adsorbed or absorbed on the sputter surface of the target and also to partly or completely remove deformed layers that may otherwise adversely affect the quality of the deposited films. The burn-in process should leave a clean surface ready for depositing thin films on production wafers.

Among the undesirable effects on the sputter target performance, is the long burn-in time required for a new sputter target. Typically, sputter targets, such as titanium targets, exhibit high film Rs uniformity during the early stages of target use. As a result, a burn-in cycle, which eliminates the surface contaminants and deformed layers of the target, must be used for at least 20 kWh before the target surface will produce good quality thin films with low Rs uniformity. As mentioned above, it is not uncommon for a standard target to be sputtered for at least 1 to 6 hours on several wafers during the burn-in cycle before the target produces high quality films. Deposition without this burn-in cycle would result in a relatively high rejection rate of wafers having poor film quality. By way of example, for titanium films, a Rₛ uniformity 0.75 to 1.0% is desirable, and 10 particles or less generated per 200 mm wafer is desired. Thus, a burn-in cycle is generally required to achieve a sputter surface that will provide the desired film properties. This requires a substantial waste of valuable preparation time and material.

Various attempts have been made to reduce, eliminate, or control the inherently undesirable characteristics resulting from the manufacturing process for sputter targets. For example, grinding, lapping, fine machining, lathes, and hand polishing has been used to remove the surface material of the target. These material removal methods are time consuming, labor intensive, costly, dirty and provide inconsistent results. While polishing to a mirror finish may provide a good surface finish, it requires extensive preparation time, usually 24 hours or more, which is unsuitable for a production environment. Further, there is no guarantee that the same result may be obtained consistently for subsequent sputter targets. An acceptable method for improving the sputter surface of a target is disclosed in U.S. Pat. No. 6,309,556, and involves chemical etching of the surface of the sputter target by immersing the surface one or more times in an etching solution, with intermediate rinsing steps.

U.S. Pat. No. 6,030,514 describes a process subjecting at least a portion of the target to a surface treatment step whereby deformed material and contaminants present on the portion are removed.

U.S. Pat. No. 6,153,315 describes the importance of a uniformly prepared sputter surface and reducing the thickness of the damaged surface layer caused by the machining operations. The '315 patent discloses a target whose surface has been diamond machined to a surface roughness of 1.0 μm or less and a deformed surface layer of less than 50 μm.

U.S. Pat. No. 6,284,111 describes a method of removing essentially the entire surface deformed layer. The '111 patent further discloses that as surface deformed layers remain on the target, deposition rates cannot be stabilized. The '111 patent further discloses a target essentially free of a surface deformed layer with a Ra between 1.0% and 10% of the mean crystal diameter (grain size) with a Ra between 0.40 μm and 4.0 μm.

U.S. Pat. No. 6,309,556 describes a method of chemically etching a target to remove essentially the entire deformed surface layer with a remaining surface roughness between 10 and 30 μ-inch. This patent discloses a process that combines mechanical finishing and etching.

Therefore, the burn-in step is a non-value step as part of the sputtering process. This non-value step that conventionally requires from at least about 1 to about 6 hours of processing downtime, or more, wastes time that cannot be used for production, impacts the entire manufacturing process, and contributes to increased product manufacturing cost. Conversely, reducing burn-in time would result in significant savings and reduced production cost. In view of the disadvantages associated with the need to burn-in a target, i.e., increased manufacturing time and possible adverse effects on the sputtering operation and the manufactured product yield, a need has developed to improve the sputtering target processing sequence to reduce the burn-in time and improve the overall manufacturing process and process yield.

In response to this need, the present invention overcomes the disadvantages noted above by providing a method which dry treats a target sputter surface with plasma using a low power magnetron sputtering apparatus.

### SUMMARY OF THE INVENTION

According to one embodiment of the present invention, a low Rs uniformity and particle generating reduced burn-in (titanium) sputtering target has been developed. The processes of the present invention provide evidence that only a thin layer, less than 100 nm, and preferably from about 25 nm to about 75 nm, which is only a fraction of the entire deformed layer thickness of metal is required to be removed unlike the conventional processes that remove a thickness of target surface layer of about 50 μm or more, depending on the selected machining method.

An additional embodiment of the present invention relates to the opportunity to reduce manufacturing costs associated with producing reduced burn-in targets. According to known processes, reduced burn-in titanium targets involved time-consuming processing steps. However, the present invention reduces this total processing time to from about 4 to about 30 minutes, and preferably from about 20 to about 30 minutes, to prepare and package a target.

In a further embodiment, the present invention is directed to a method of dry treating a target sputter surface prior to using the target for film deposition in a commercial tool, comprising preparing a target assembly and securing the target assembly in a low pressure chamber of a magnetron sputtering apparatus and applying from between about 0.2 kW to about 4 kW to the target for a period of time less than 30 minutes, and preferably between from about 20 to about 30 minutes, to produce a surface dry surface condition using plasma on an exposed surface of the target to effectively reduce inherently undesirable contaminants on the sputter surface by removing a target surface layer of only from about 25 nm to about 75 nm (a fraction of the deformed layer thickness). The target is then removed from the apparatus and packaged, preferably with a special enclosure that is preferably metallic.

### BRIEF DESCRIPTION OF THE DRAWINGS

Other objects, features and advantages will occur to those skilled in the field from the following description of preferred embodiments and the accompanying drawings, of which:

FIG. 1 is a cross-sectional schematic drawing of a magnetron sputtering apparatus containing a target assembly;

FIG. 2 is a comparative graph showing a surface section analysis of surface layer removal;

FIG. 3 is a graph showing surface hardness change;

FIG. 4 is a comparative graph showing improvement in particle performance via reduced particle generation; and

FIGS. 5a-c are a series of graphs showing particle performance on Ti, TiN, and TiN—Ti bilayer films respectively.

### DETAILED DESCRIPTION OF THE INVENTION

The present invention relates to the treatment of a wide variety of sputtering targets and preserving such targets during shipment and storage before installation into commercial sputtering tools. One embodiment of the present invention is intended to minimize the total burn-in time. These objectives are met by the novel dry surface treatment of the target that is the subject of the present invention.

Generally, sputtering targets are manufactured by conventional processing steps such as selecting a target metal/alloy material, melting it and casting it into an ingot or fabricate ingots using powder metallurgy methods as would be readily understood by those skilled in the metallurgy field. The ingot is then worked, either by hot-working, cold-working or a combination thereof and heat treating to form the final manufactured target. Other conventional steps may include machining, bonding, if required, final machining and cleaning, before the target is ready for use in sputtering.

Therefore, according to one embodiment of the present invention, the conventionally produced target is subjected to a surface treatment step. The purpose of the surface treatment step is to produce a surface similar (in terms of properties, but not in appearance) to one that would be produced by a burn-in sequence but without the actual burning-in. According to one embodiment of the present invention, the inventive surface treatment methods provided herein significantly reduces burn-in time. Thus, if the target surface can be made to resemble a target that has been subjected to a burn-in process (in terms of cleanliness, hardness, etc.), less burn-in time is required, thus significantly and advantageously improving the process yield as well as the economics of the overall device manufacturing process.

The sputter target material is preferably selected from the group consisting of titanium, aluminum, copper, molybdenum, cobalt, chromium, ruthenium, silver, platinum, gold, tungsten, silicon, vanadium, nickel, iron, manganese, germanium, iridium and alloys thereof.

As used herein, the term “target assembly” includes sputtering targets which are either one piece or which include a supporting target backing plate. Preferably, the magnetron apparatus able to generate plasma at the sputter surface of the target that can be rotated around an axis (perpendicular to the sputter face) at the center of the target, by a mechanical means, to treat the sputter surface partially or completely. The surface area covered by this treatment can be altered by changing the magnet pack configuration. Therefore, sputter targets (ideally, for example, for up to 300 mm wafers) with various diameters can be treated using this method. In addition, the strength of the magnetic field can be altered to suit various metal alloy sputter targets by choosing appropriate magnets.

According to one example, the substrate to be coated, such as, for example, a wafer, generally has a titanium film with a Rₛ uniformity in excess of about 1.0%. Target assemblies that produce films having certain Rₛ uniformity values are generally rejected outright by the industry. Titanium sputter targets that produce titanium films having Rₛ uniformity between from about 0.75 to about 1.0% generally require a long burn-in period (equivalent to about 20 kwh life or more).

According to one embodiment, the novel magnetron sputtering apparatus of the present invention can be operated between from about 0.2 kW to about 4 kW, more preferably between about 0.2 kW and about 1.0 kW and most preferably between about 0.2 kW and about 0.5 kW for a period of time between about 15 and about 30 minutes, more preferably between from 20 to about 30 minutes.

The magnetron sputtering apparatus should treat the surface of the target assembly in a low pressure chamber using a plasma. A forced air cooling, or other efficient cooling system can be used to extract heat from the target assembly in a controlled manner. The process conditions recited above will desirably treat the surface of the target assembly so that the Rₛ uniformity of a titanium film can be reduced by a magnitude as large as about 25%

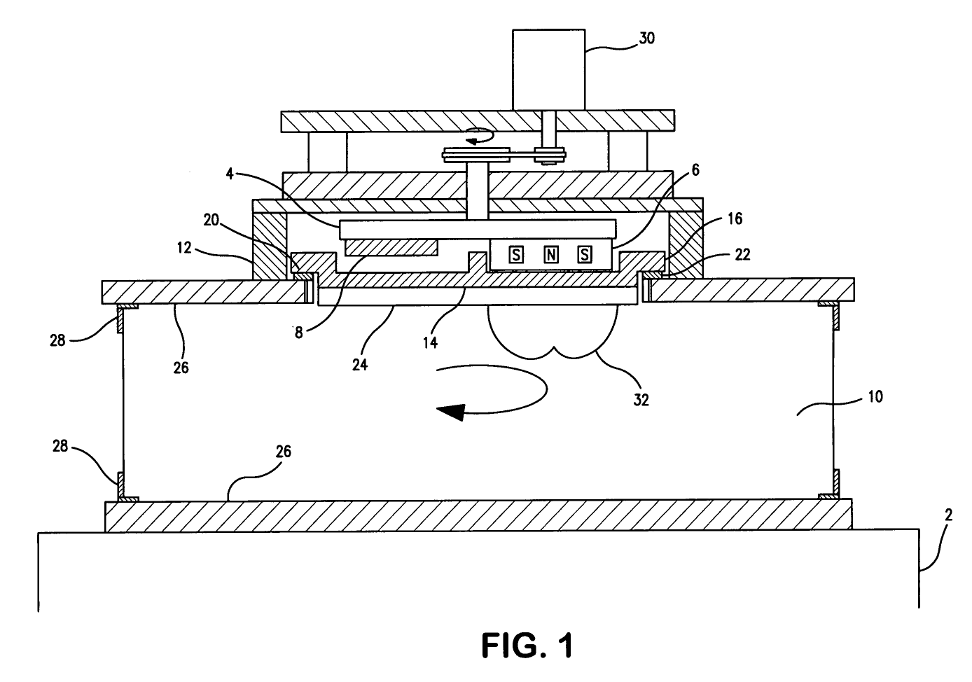

According to one preferred embodiment of the present invention, the inventive surface treatment can be carried out using a magnetron sputtering apparatus such as, for example, the type shown in FIG. 1, wherein the apparatus 2 comprises a rotating disk 4 containing a magnet assembly 6 balanced with a counterweight 8. Magnet assembly 6 consists of individual magnets arranged in a desired pattern (not shown). The rotating disk 4 is secured to the vacuum chamber 10 by electrical insulating blocks 12. Disposed beneath the rotating disk assembly 4-6-8 is a target assembly 14 composed of backplate 16, secured to a target 24 by Viton™ ‘O’ rings 20 and Teflon™ insulator ring 22. The target has its surface 24 facing “into” the vacuum chamber 10. The vacuum chamber 10 comprises support plates 26 with a side Viton vacuum seal 28, such as the Viton™ elastomer. A drive motor 30 drives the rotating disk 4 and thus rotates magnet assembly 6. When power is applied to the sputter target, a rotating plasma 32 is produced in the low pressure chamber that can treat the sputter surface of the target component. By selecting a desired power and time, as discussed below, a plasma 32 is made to rotate and substantially uniformly treat the target surface 24 (unlike conventional commercial magnetrons that use localized concentric circles). This novel treatment can effectively reduce the Rₛ uniformity of the deposited titanium film by a magnitude as large as about 25%.

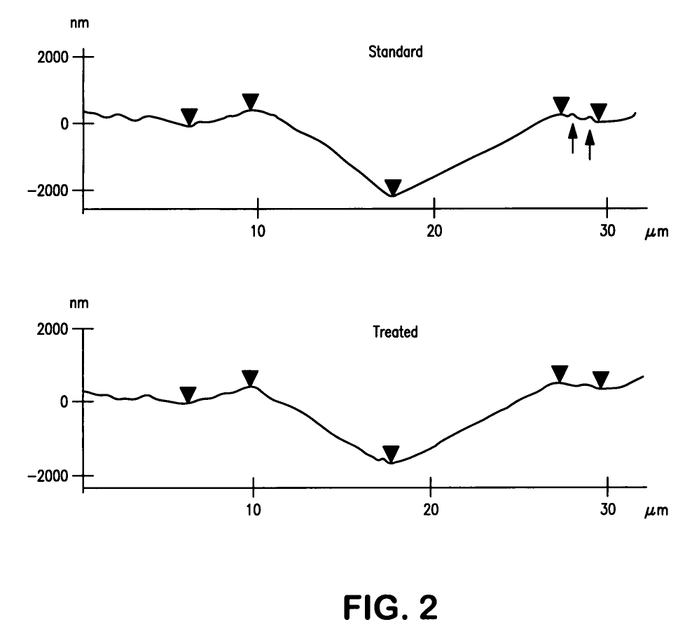

It has now further been determined that the above-identified process is effective when a very thin surface layer of only between about 25 nm and about 75 nm has been removed. The variance is due to the different amounts of material removed at the peaks and valleys left at the surface from the machining operation. (See FIG. 2). The measurements have error of the order of about +/−10 nm. The sharp peaks (shown by the arrows) are no longer present after the treatments of the present invention. In order to measure the thickness of the deformed layer removed by the treatments of the present invention, two sets of measurements were conducted (before and after the treatment that correspond standard and treated targets) on the same area of the surface using an atomic force microscope (AFM). An indentation was used to identify the area of interest. With regard to the surface topography changes due to this treatment, similar observations were made in the vicinity of, and away from the indentation. For clarity and ease of depiction, results from an area in the vicinity of the indentation are reported here.

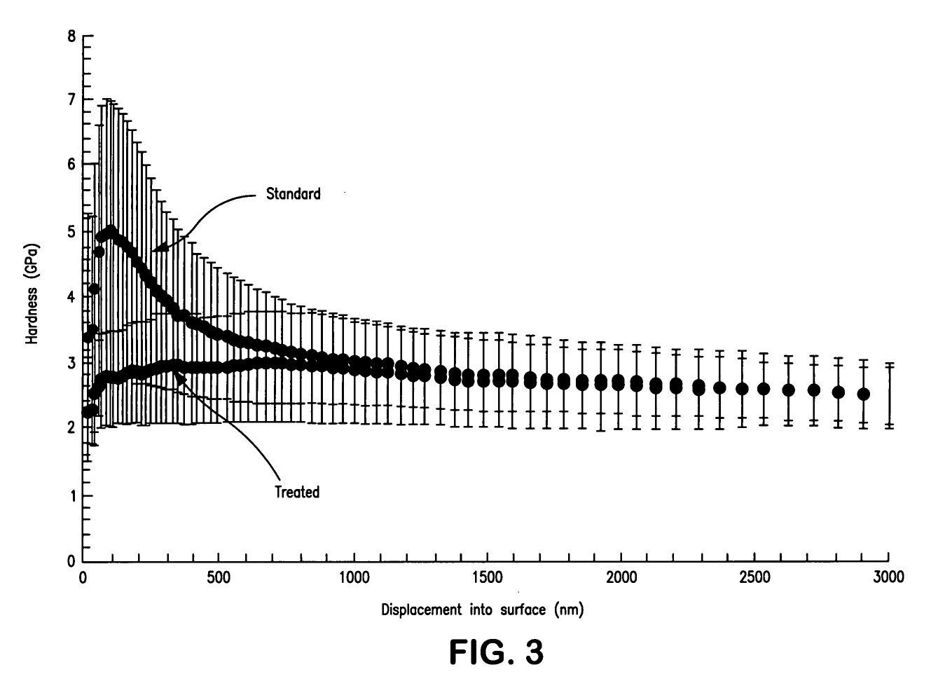

It is also apparent that heating of the sputter surface softens the deformed surface layer (see FIG. 3), further improving target microstructure and, as a result, sputtered film characteristics. In order to generate hardness data as a function of the depth into the surface, nano-indentation tests were carried out on the surface, before and after the treatment that correspond standard and treated targets. The results (hardness drop below 800 nm thickness) show that the surface layer softened due to the treatments of the sputter surface. Evidences of microstructural changes that favor softening of the deformed layer have also been found.

Therefore, an improvement of the present invention is a target treated according to preferred embodiments of the processes of the present invention disclosed herein, to a condition wherein a portion (thickness) of the target's surface layer has been removed in an amount of from about 25 nm to about 75 nm and wherein the target's surface hardness has been reduced.

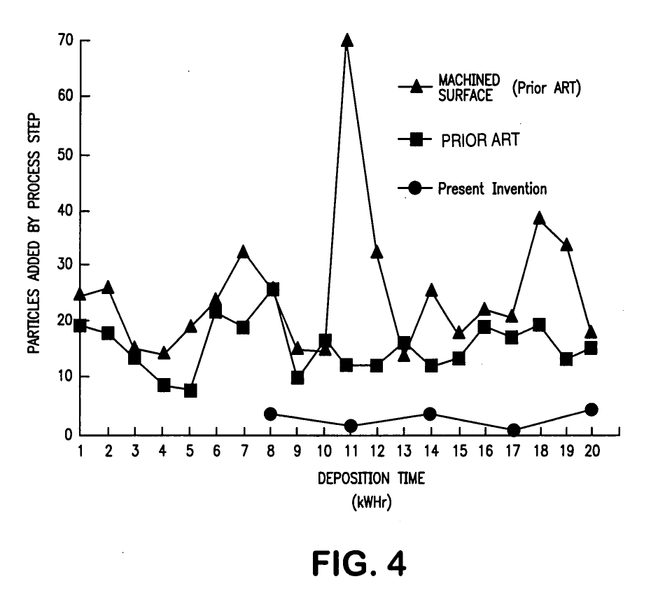

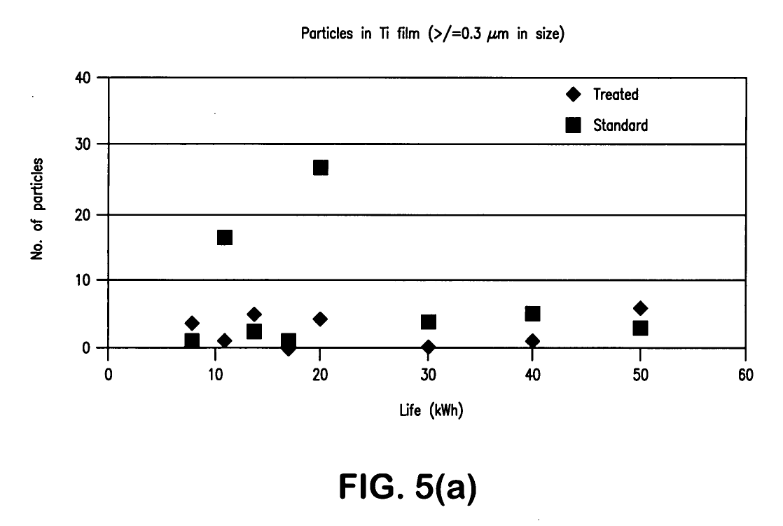

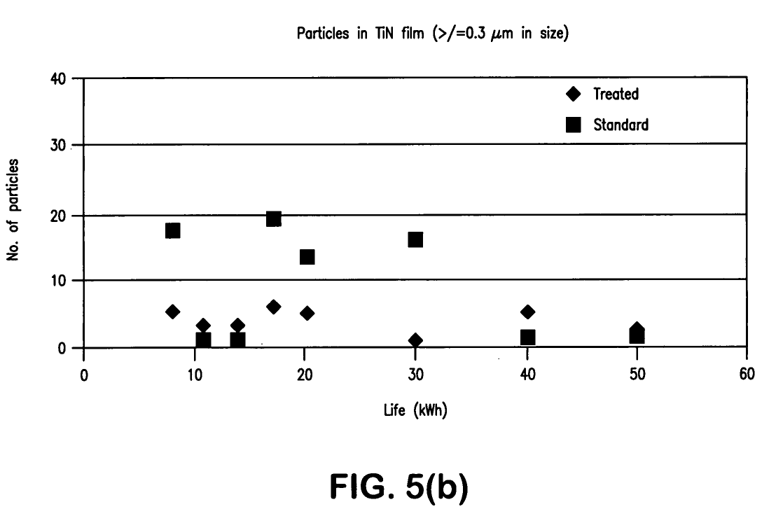

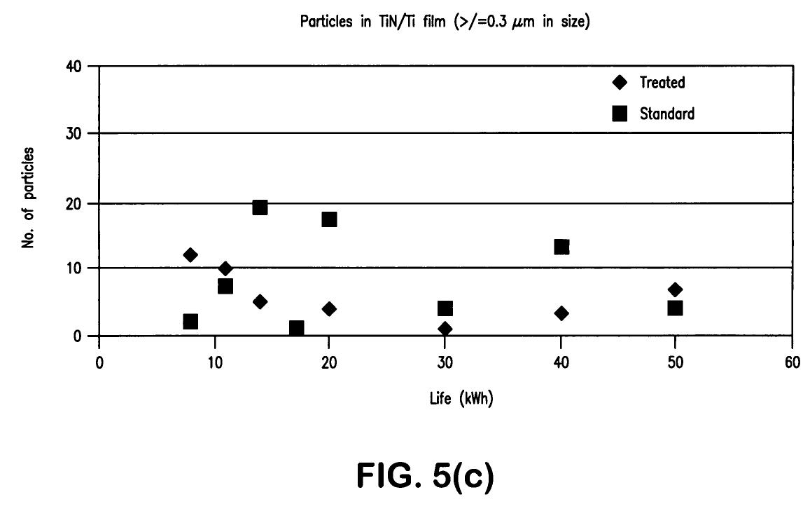

It has now been determined that, implementing procedures according to the present invention results in a reduction of conventional burn-in time of at least about 50% in titanium and other targets. Additionally, films, such as, for example titanium thin films, deposited on the wafers with this target have significantly fewer particles on the film. (See FIG. 4). Furthermore, it has now been determined that the processes of the present invention are highly effective for materials and thin films, such as, for example, Ti, TiN, bi-layers of TiN & Ti films, etc. FIGS. 5a-c describes the in-film particle performance improvement for disclosed Ti film, TiN and bi-layers of TiN & Ti films.

In the case of the TiN film, nitrogen is injected to the plasma atmosphere for reactive sputtering to take places, thereby producing a TiN film. In the case of bi-layer films, nitrogen is, alternately, introduced to/removed from the plasma atmosphere to produce layers of Ti and TiN films. For any other target materials, a suitable gas can be introduced to change the deposited film characteristics and composition. For example, indium-tin-oxide (ITO) sputtering requires oxygen to be supplied to deposit a transparent metal oxide film. Therefore, the present invention would be useful in achieving a reduction in generated particles.

From a production perspective, the reduced burn-in titanium targets that have been developed according to the present invention reduce the preparation time by about 50% or more of the conventional burn-in time. Further, the present inventive surface treatment, combined with packaging time, requires less than about 30 mins., preferably from about 20 mins. to about 30 mins.

In addition, the treatments of the present invention remove contaminants from the sputter surface. As described in Table 1, one of the preferred processes of the present invention removed about 40% of the surface carbon, resulting in more titanium available to the surface. Surface chemistry of the target before the treatment corresponds to a standard target whereas the surface after the treatment corresponds to a treated target. Results were generated using x-ray photoelectron spectroscopy (XPS) studies of the surfaces. In the standard target, (i.e. before XPS measurement), the surface was in contact with packaging plastic bag. This was allowed in order to reveal the possibility of organic compound “pick-up” from the plastic by the sputter surface of a standard target. All necessary measures were observed to simulate the actual steps of cleaning and packaging standard targets, and also mimic packaging of treated targets with enclosures.

TABLE 1

| | Titanium | Oxygen | Carbon |
|---|---|---|---|
| Standard Target | 15.4 | 39.4 | 40.2 |
| Treated Target | 32.5 | 39.7 | 23.4 |

Concentration of elements in atomic percent (at %)

Known methods involve complex steps (precision machining, polishing, wet etching, or a combination of more than above mentioned methods, etc.) that required longer processing time. In particular, wet methods involve careful handling and pose the risk of cosmetic damage of areas next to the sputter surface. However, none of the previously known methods satisfy the need in the field to completely remove the deformed metal layer and/or to make the surface as smooth as possible. Preferred embodiments of the present invention obviate this need.

Preferred embodiments of the present invention further characterize the level of treatment necessary to achieve suitable metallic and nitride film properties, allow for the treatment of bi-layers of films, and also expand into the area of surface softening caused by target heating due to the treatment.

According to preferred embodiments, the present invention is also directed to methods and apparatuses to prepare inventive target surfaces in an extremely uniform fashion, as a thin layer thickness of from about 25 nm to about 75 nm is removed substantially homogeneously from the target surface in a short period of time. This is in strong contrast to known, relatively slow, “wet” methods. Additionally, external contaminants that can come from an acid or slurry would not be present in the dry methods according to embodiments of the present invention. The present invention is an environment-friendly process which does not produce extra residues (acid solutions, slurries etc.) during reduced burn-in surface preparation time. The present invention also identifies measurable surface conditions following treatment. Data presented in Table 2 confirms that the treated target has reduced contaminants and more titanium available than a standard target and it is believed that the treated target would have much less contaminants than a conventional, “wet” processed target.

TABLE 2

| | Rs Uniformity | Rs Uniformity | |
|---|---|---|---|
| | Standard | Treated | % Drop in |
| Life (kWh) | Target | Target | Rs Uniformity |
| 8 | 1.18 | 0.86 | 27.11 |
| 11 | 1.20 | 0.89 | 25.83 |
| 14 | 1.15 | 0.90 | 21.73 |
| 17 | 1.16 | 0.87 | 25.00 |
| 20 | 1.21 | 0.91 | 24.79 |
| 25 | 1.18 | 0.91 | 22.88 |
| 30 | 1.19 | 0.90 | 24.36 |
| 35 | 1.09 | 0.89 | 18.34 |
| 40 | 1.20 | 0.78 | 35.00 |
| 45 | 0.96 | 0.90 | 6.25 |
| 50 | 0.92 | 0.91 | 1.08 |

According to one embodiment, the present invention is a one-step process that is significantly faster than known multi-step processes, leading to significant savings of time and resources, in terms of enhanced production. Moreover, being an environment-friendly process, no extra cost of toxic or other waste disposal is involved. The fab's ability to put tools into production faster and the reduced Rs uniformity and particle formation, provides strong economic incentives for the target user.

In preferred embodiments, the processes and apparatuses of the present invention conditions flat titanium, and other targets, for reduced burn-in time. The time required (less than about 30 min.) for the treatment has also been optimized for these targets. This duration can be further reduced by optimizing an efficient cooling system, superior to conventional forced air cooling (ambient temperature).

According to yet another embodiment, processes of the present invention cause temperature rises in the target sputter surface which has been measured (less than about 70° C.) on the backing plate side. A large variety of targets are solder bonded using low melting alloys. In the case of solder bonded targets, a careful review of the solder material is required before subjecting such a target to the reduced burn-in treatment. However, most solder and diffusion bonded targets are safe to be used for the reduced burn-in treatment, as the bond strength is sufficiently large in this temperature range (less than about 100° C.). Once the target is treated, it is cooled to room temperature and re-packaged using a metal enclosure to avoid contact between the plastic packaging (e.g. plastic bag) and the sputtering surface.

The power, treatment time and process parameters are determined by running test targets under various conditions to achieve the desired surface characteristics. In order to evaluate the performance of the reduced burn-in target, an Endura™ 5500 tool (Applied Materials Inc., Santa Clara, Calif.) was used. The properties of thin films (Rs uniformity, in-film particle content), and also, the response of the target were monitored. For example, all the data recorded for a 50% reduced burn-in titanium target show comparable or better results than a target subjected to standard burn-in. Hence, a reduced burn-in, flat sputtering target can be prepared rather quickly in an inexpensive way.

Preferred embodiments of the present invention can be practiced for a range of targets having varied, desired and predetermined characteristics including shape of the target (preferably planar and round), and target size (preferably for wafers between about 150 nm to about 300 mm wafers). Further preferred embodiments of the present invention can be practiced on targets having varied types of bonding between target and backing plate, such as, for example, diffusion bonded targets and some solder bonded targets having adequate bond strength at about 100° C. In addition, preferred embodiments of the present invention contemplate using a metal enclosure, such as, for example, an aluminum electronic grade foil for packaging the treated, reduced burn-in target.

Using the magnetron sputtering apparatus as described in FIG. 1, sputter target was subjected to 0.3 kW power for 20 mins. at 2.5 micron argon for the desired treatment. After testing this target with an Endura 5500 tool, Rₛ uniformity values of thin films were determined applying forty-nine (49) point measurements and 3 mm edge exclusion on 200 mm wafers.

Conventionally, the process condition for normal burn-in is an incremental step process to a maximum power of at least 3 kW for at least 6 hours. Using the novel treatments of the present invention, the burn-in time necessary to qualify the target for use in production is significantly reduced to unexpectedly low levels. The novel treatments of the present invention involve minimal surface removal thereby increasing the number of usable deposited wafers for a given sputtering target.

Once the surface of the target assembly is treated, at least the treated portion of the target is then placed in an enclosure, to protect the treated portion from possible contamination. The enclosure prevents contact between the surface-treated portion of the target and any subsequently applied packaging material or enclosure surrounding the target and the enclosure. The surface treatment combined with the enclosure substantially reduces potential and actual contamination on the target surface resulting in reduced arcing, presence of organic radicals and carbon levels during burn-in. Consequently, the burn-in time reduction is maintained. The enclosure and target assembly optionally may then be further enclosed in a plastic enclosure such as a double-plastic bag for clean room use. The enclosure optionally may be evacuated for shipping and storing purposes. Preferably, the initial enclosure is metallic, as the metallic enclosure can prevent contact or exposure between a plastic bag and the target surface. Plastic or polymeric materials tend to contaminate the target surface by providing a source of organic material which would be detrimental if present in the sputtering process. A metallic enclosure eliminates contact between the target and any plastic and any source of organic radicals and prevents degassing during sputtering and/or burn-in.

Without departing from the spirit or scope of the present invention, the invention in its broader aspects is therefore not limited to the specific details and illustrative example shown and described. Accordingly, departures may be made from such details without departing from the spirit or scope of applicants' general inventive concept. Therefore, applicants desire to be limited only by the scope of the following claims and equivalents thereof.

What is claimed is:

1. A method of dry treating a target surface prior to using the target for thin film deposition comprising:
a) preparing a target assembly having a sputter surface and securing said target assembly in a low pressure magnetron sputtering apparatus;
b) providing and applying power between about 0.2 kW and about 4.0 kW to the target assembly for a period of time between about 15 and about 30 minutes to produce a plasma dry treatment of the sputter surface of the target to reduce contaminants from the surface by removing a thin target surface layer of less than about 75 nm; and
c) removing the treated target assembly from the magnetron sputtering apparatus.

2. The method of claim 1 wherein the magnetron sputtering apparatus is rotatable and the magnetic component of the magnetron sputtering apparatus is disposed on less than a 180° arc measured at the axis of rotation of the apparatus so as to produce a rotatable sputtering ion plasma on the surface of the target.

3. The method of claim 1 wherein the target surface is treated for a time period between about 20 and about 30 minutes and a power of between about 0.2 kW and about 0.5 kW.

4. The method of claim 3 wherein the target surface is treated in a low pressure atmosphere.

5. The method of claim 6 where the low pressure atmosphere comprises argon.

6. The method of claim 1 further comprising the steps of providing an enclosure and placing the surface treated portion of the target assembly in an enclosure to protect said surface treated portion during storage and shipment.

7. The method of claim 6 wherein the enclosure comprises a metallic element.

8. The method of claim 7 wherein the metallic element is a thin metal foil.

9. The method of claim 1 wherein the target material selected from the group consisting of: titanium, aluminum, copper, molybdenum, cobalt, chromium, ruthenium, silver, platinum, gold, tungsten, silicon, vanadium, nickel, iron, manganese, germanium, iridium and alloys thereof.

10. The method of claim 1 wherein the thin film is selected from the group consisting of titanium, titanium nitride, titanium nitride/titanium bilayer, and mixtures thereof.

11. The method of claim 2 wherein the magnetic component comprises FeNdB alloys.

12. The method of claim 2 further comprising the step of:
d) installing the treated target assembly into a magnetron sputtering apparatus to clean a sputter target surface for about 15 to about 30 minutes at a power of from about 0.2 kW to about 0.5 kW.

13. The method of claim 12 wherein the target surface is treated for a time period between about 20 to about 30 minutes and a power of between about 0.2 kW and about 0.5 kW.

14. The method of claim 12 wherein the target surface is treated to remove a thickness of surface layer of from about 25 nm to about 75 nm.

15. The method of claim 1 further comprising the step of softening the sputter surface.

16. The method of claim 15 wherein the softening of the sputter surface occurs via heating.

17. The method of claim 1, wherein the magnetron apparatus generates a plasma at the sputter surface of the target that can be rotated around an axis perpendicular to the sputter face at the center of the target, by a mechanical means, to treat the sputter surface partially or completely.

18. A treated target assembly made according to the method of claim 1.

19. A treated target assembly made according to the method of claim 1, wherein the layer sputtered has an Rs uniformity of 1 or less.

20. A treated target assembly made according to the method of claim 12.

21. The treated target assembly of claim 1 wherein the target material is selected from the group consisting of: titanium, tantalum, aluminum, copper, molybdenum, cobalt, chromium, ruthenium, silver, osmium, iridium, platinum, gold, tungsten, silicon, vanadium, nickel, iron, manganese, germanium, and alloys thereof.

22. The treated target assembly of claim 12 wherein the target material is selected from the group consisting of: titanium, tantalum, aluminum, copper, molybdenum, cobalt, chromium, ruthenium, silver, iridium, platinum, gold, tungsten, silicon, vanadium, nickel, iron, manganese, germanium, and alloys thereof.

23. A method of dry treating a target surface prior to using the target for thin film deposition comprising:
a) preparing a target assembly having a sputter surface and securing said target assembly in a low pressure magnetron sputtering apparatus;
b) providing and applying power between about 0.2 kW and about 4.0 kW to produce a plasma dry treatment of the sputter surface of the target to reduce contaminants from the surface by removing a thin target surface layer of less than about 75 nm; and
c) removing the treated target assembly from the magnetron sputtering apparatus.
